(19) United States
(12) Patent Application Publication
(10) Pub. No.: US 2026/0336170 A1
(43) Pub. Date: Oct. 29, 2026

(54) IMPRINT METHOD, ARTICLE MANUFACTURING METHOD, AND MOLDING APPARATUS

(71) Applicant: CANON KABUSHIKI KAISHA, Tokyo (JP)

(72) Inventor: HISASHI NAMBA, Tochigi (JP)

(21) Appl. No.: 19/542,923

(22) Filed: Feb. 18, 2026

(30) Foreign Application Priority Data
Apr. 25, 2025 (JP) 2025-072882

(51) Int. Cl. B29C 43/58; B29C 43/18; G03F 7/00

(52) U.S. Cl. CPC B29C 43/58; B29C 43/18; G03F 7/0002; B29C 2043/5875

(57) ABSTRACT

A molding apparatus configured to mold a composition disposed in a plurality of shot regions on a substrate by using a mold includes a discharge unit configured to discharge the composition onto the substrate, a drive mechanism configured to drive the substrate relative to the discharge unit, at least one memory storing instructions; and at least one processor executing the stored instructions causing the molding apparatus to: discharge the composition from the discharge unit at a predetermined pitch onto the substrate driven by the drive mechanism, and adjust so that a sum of a width of the shot region in a driven direction in which the shot region is driven by the drive mechanism and an interval between the shot region and a shot region adjacent in the driven direction becomes an integer multiple of the pitch.

### BACKGROUND

### Field of the Technology

The present disclosure relates to an imprint method, an article manufacturing method, and a molding apparatus.

### Description of the Related Art

An imprint technique is known in which a pattern of resin is formed on a substrate by forming uncured resin on the substrate using a mold. In the imprint technique, a fine structure in the order of nanometers can be formed on the substrate. In an imprint apparatus employing a photo-curing method, a pattern is formed as follows. First, discharge material (imprint material, photocurable resin, and the like) is discharged in a field that is an imprint region (also referred to as a shot region) on the substrate. Next, a mold is pressed against the discharge material on the substrate. Next, after the discharge material is cured by irradiation with light such as ultraviolet light, a pattern of solidified discharge material is formed on the substrate by separating the mold.

In such an imprint apparatus, an inkjet-type discharge apparatus is used in order to discharge the discharge material onto the substrate. During a discharge operation, discharge is performed onto a region to be imprinted while the substrate is moved at a constant speed. In the imprint apparatus, such a discharge operation and an imprint operation are alternately repeated. WO2007/120537 describes a technique of reducing the number of substrate movements by performing a discharge operation collectively for a plurality of fields.

However, when discharge is simply performed continuously for a plurality of fields (a plurality of shot regions), a position at which discharge material is discharged may gradually deviate from the field in some cases. When a deviation amount becomes large, imprinting defects may occur in some cases due to discharge material protruding from the field and the like.

### SUMMARY

The present disclosure is directed to provide an imprint method that suppresses occurrence of imprinting defects even when discharge is performed continuously onto a plurality of shot regions.

According to an aspect of the present disclosure, a molding apparatus configured to mold a composition disposed in a plurality of shot regions on a substrate by using a mold includes a discharge unit configured to discharge the composition onto the substrate, a drive mechanism configured to drive the substrate relative to the discharge unit, at least one memory storing instructions; and at least one processor executing the stored instructions causing the molding apparatus to: discharge the composition from the discharge unit at a predetermined pitch onto the substrate driven by the drive mechanism, and adjust so that a sum of a width of the shot region in a driven direction in which the shot region is driven by the drive mechanism and an interval between the shot region and a shot region adjacent in the driven direction becomes an integer multiple of the pitch.

Features of the present disclosure will become apparent from the following description of embodiments with reference to the attached drawings. The following description of embodiments is described by way of example.

### BRIEF DESCRIPTION OF DRAWINGS

FIG. 1 is a diagram showing a configuration of an imprint apparatus of an embodiment.

FIGS. 2A to 2D are diagrams showing a discharge operation of the imprint apparatus shown in FIG. 1.

FIGS. 3A to 3C are diagrams showing a continuous discharge operation of a plurality of fields.

FIGS. 4A and 4B are diagrams showing a method for adjusting grid size.

FIG. 5 is a diagram for explaining an article manufacturing method.

### DESCRIPTION OF THE EMBODIMENTS

Hereinafter, embodiments of the present disclosure will be explained in detail with reference to the attached drawings. It should be noted that the following embodiments do not limit the disclosure according to the claims. Although a plurality of features are described in the embodiments, not all of the plurality of features are necessarily essential to the disclosure, and the plurality of features may be freely combined.

### <Imprint Apparatus>

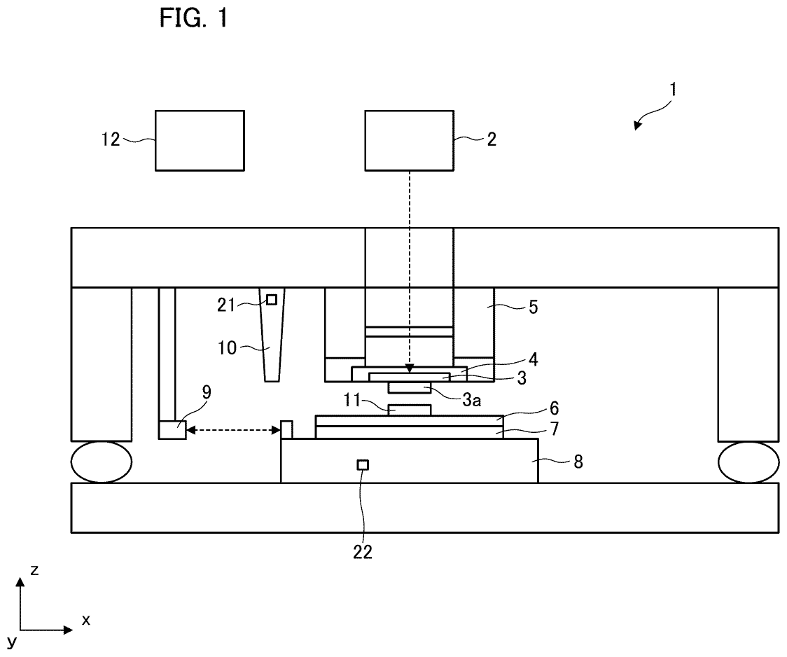

FIG. 1 is a diagram showing a configuration of an imprint apparatus 1 of the present embodiment. That is, the imprint apparatus 1 corresponds to a molding apparatus. The imprint apparatus 1 is an apparatus for forming a pattern of a cured product to which an uneven pattern 3a on a mold 3 is transferred by imprinting a discharge material 11 supplied onto a substrate 6 with the mold 3, and applying energy for curing to the discharge material 11. The imprint apparatus 1 is used for device manufacturing, such as manufacturing of semiconductor devices, as articles. The discharge material 11 is also called an imprint material, a resin, a coating material, or the like. An imprint apparatus using a photocurable resin material as the discharge material 11 is explained here.

The imprint apparatus 1 is provided with a mold holding unit 4 for holding the mold 3, and a mold drive mechanism 5 that moves in a vertical direction in order to imprint the mold 3 on the substrate 6. The imprint apparatus 1 is provided with a substrate holding unit 7 for holding the substrate 6, and a substrate stage 8 that is movable in a horizontal direction including at least an x direction, a y direction, and a rotational direction in an xy plane. That is, the substrate stage 8 functions as a drive mechanism that drives the substrate relative to a discharge unit. For positioning control of the substrate stage 8, an interferometer-type displacement meter 9 generally used in positioning tables is used. Alternatively, a linear encoder may be used instead of the displacement meter 9.

A discharge apparatus 10 discharges the discharge material 11 for forming a pattern onto a region on the substrate 6, the region having the same size as the uneven pattern 3a. That is, the discharge apparatus 10 functions as a discharge unit that discharges a composition onto the substrate. During a discharge operation, discharge is performed while the substrate stage 8 is moved at a constant speed.

The discharge material 11 is a composition curable by irradiation with light or by heating. Of these, the discharge material 11 that is cured by light contains at least a polymerizable compound and a photopolymerization initiator, and may contain a non-polymerizable compound or a solvent as necessary. The non-polymerizable compound is at least one selected from the group consisting of a sensitizer, a hydrogen donor, an internal release agent, a surfactant, an antioxidant, a polymer component, and the like.

The imprint apparatus 1 is provided with a light source 2 for curing the discharge material 11 by light. A UV light source having a wavelength of 400 nm or less is generally used as the light source 2.

The mold drive mechanism 5, the substrate stage 8, the discharge apparatus 10, and the light source 2 are controlled by a control unit 12. The control unit 12 may include a plurality of controllers (not shown). The substrate stage 8 has a stage control unit 22. The stage control unit 22 controls the substrate stage 8 in accordance with an instruction from the control unit 12. The discharge apparatus 10 has a discharge control unit 21. The discharge control unit 21 controls the discharge apparatus 10 in accordance with instructions from the control unit 12 and the stage control unit 22. That is, the control unit 12 causes the composition to be discharged from the discharge unit at a predetermined pitch (interval) onto the substrate driven by the substrate stage 8.

### <Explanation of Discharge Operation>

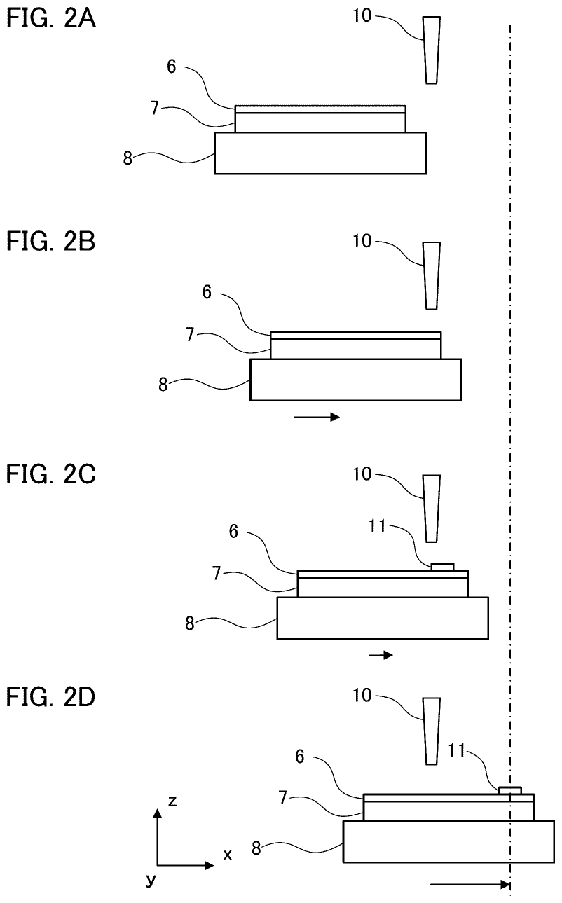

FIGS. 2A to 2D are diagrams showing a discharge operation by the discharge apparatus 10. A dotted line in FIGS. 2A to 2D indicates an imprint position of the mold 3. FIGS. 2A to 2D show an example in which the discharge material 11 is discharged onto a predetermined field (discharge region, shot region) by discharge being performed from the discharge apparatus 10 while the substrate stage 8 moves in a stage movement direction (the +x direction in this example). A state is shown in which, during the discharge operation in FIGS. 2A to 2D, the position of the discharge apparatus 10 does not change while the position of the substrate stage 8 changes.

FIG. 2A shows positions of the discharge apparatus 10 and the substrate stage 8 at the start of the discharge operation. FIG. 2B shows a state in which the substrate stage 8 is moved at a constant speed, and a discharge start position in the discharge region on the substrate 6 is located below the discharge apparatus 10 in the gravitational direction (the −z direction). At the timing of FIG. 2B, the discharge apparatus 10 starts discharging. The substrate stage 8 continues to move while maintaining a constant speed operation, starts deceleration after reaching a discharge completion position shown in FIG. 2C, and stops. In contrast, the discharge apparatus 10 completes the discharge operation. As a result, the discharge operation onto the discharge region is completed. That is, FIGS. 2A to 2C correspond to a driving step, and FIGS. 2B to 2C correspond to a discharge step.

Next, in order to perform an imprint operation, the substrate stage 8 is moved so that the position of the discharge region corresponds to an imprint position as shown in FIG. 2D. It should be noted that although the substrate stage 8 is moved in one direction in FIGS. 2A to 2C, by performing reciprocal movement, the discharge operation can be performed on a return path as well, and if a discharge position in the x direction or the y direction is changed on the outward path and the return path, the discharge material 11 can be discharged at higher density. It should be noted that although the substrate stage 8 moves in FIGS. 2A to 2D, the discharge apparatus 10 or the mold 3 may be moved.

After the discharge operation in FIGS. 2A to 2D, by lowering the mold 3 (not shown in FIGS. 2A to 2D), the mold 3 is impressed on the discharge region of the substrate 6. Then, the discharge region is irradiated using the light source 2 to cure the discharge material 11. After curing, the mold 3 is raised, and pattern formation is completed. In a case in which a pattern is formed on an entire surface of the substrate 6, such a discharge operation and an imprint operation are repeatedly performed. It should be noted that, in FIGS. 2A to 2D, for explanation, an example is shown in which a discharge operation is performed in one field (discharge region, imprint region, or shot region) and an imprint operation is performed for that field. In the present embodiment, as will be described below, after a discharge operation is performed continuously in a plurality of fields, an imprint operation is performed continuously.

### <Continuous Discharge Operation>

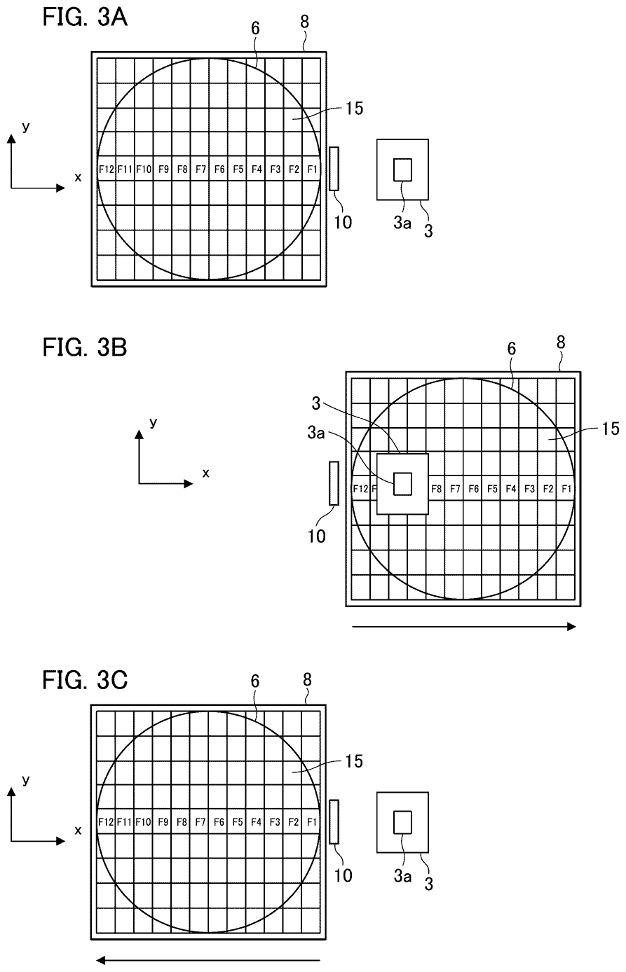

Next, with reference to FIGS. 3A to 3C, a state in which, after a discharge operation is performed continuously in a plurality of fields, an imprint operation is performed continuously, will be explained. FIGS. 3A to 3C are plan views of the substrate 6 from above, and the substrate 6 is divided into a plurality of fields 15. A processing method in a case in which imprinting is performed from field F1 to field F12 will be explained here. In the following explanation, matters common to each field are described as field 15, and matters related to individual fields are described as field F1 and the like.

FIGS. 3A to 3C show a state in which the position of the uneven pattern 3a on the mold 3 and the position of the discharge apparatus 10 are fixed, and a position of the substrate 6 moves due to the movement of the substrate stage 8. A state in which transition occurs chronologically in the order of FIG. 3A to FIG. 3C is shown.

In FIG. 3A, the discharge apparatus 10 is on the right side of the substrate 6. Then, the substrate stage 8 is driven at constant speed in the +x direction, and a discharge operation by the discharge apparatus 10 is performed. When the substrate 6 reaches the right side of the discharge apparatus 10 (FIG. 3B), next, the substrate stage 8 is driven at constant speed in the −x direction, the substrate 6 moves to the left side of the discharge apparatus 10, and the substrate stage 8 performs reciprocal driving (FIG. 3C). When the substrate stage 8 performs reciprocal driving, the discharge apparatus 10 discharges the discharge material 11 onto fields F1 to F12, and thereafter, the mold 3 is impressed on the discharge region in order from field F1 to F12.

In this manner, the discharge material 11 is first discharged onto a plurality of fields 15, and thereafter, the mold 3 is impressed on the fields 15 to which the discharge material 11 has been discharged, one field at a time. By doing so, the movement amount of the substrate stage 8 can be reduced compared with discharging the discharge material 11 and impressing the mold 3 for each field, and throughput is improved.

The discharge apparatus 10 has a discharge material arrangement pattern set for how the discharge material 11 is to be discharged onto the field 15. In a case in which the discharge material 11 is discharged continuously to a plurality of fields 15, there is insufficient time available when moving from one field 15 to an adjacent field 15. For this reason, when a discharge material arrangement pattern is held for each field 15, reading of the discharge material arrangement pattern cannot be performed in time when moving from one field 15 to an adjacent field 15.

Accordingly, discharge material arrangement patterns of a plurality of fields 15 are combined, and a combined discharge material arrangement pattern is created, and the discharge material 11 is discharged onto the substrate 6 in accordance with the combined discharge material arrangement pattern. In the case of FIGS. 3A to 3C, one discharge material arrangement pattern is created by combining discharge material arrangement patterns for one row of fields F1 to F12.

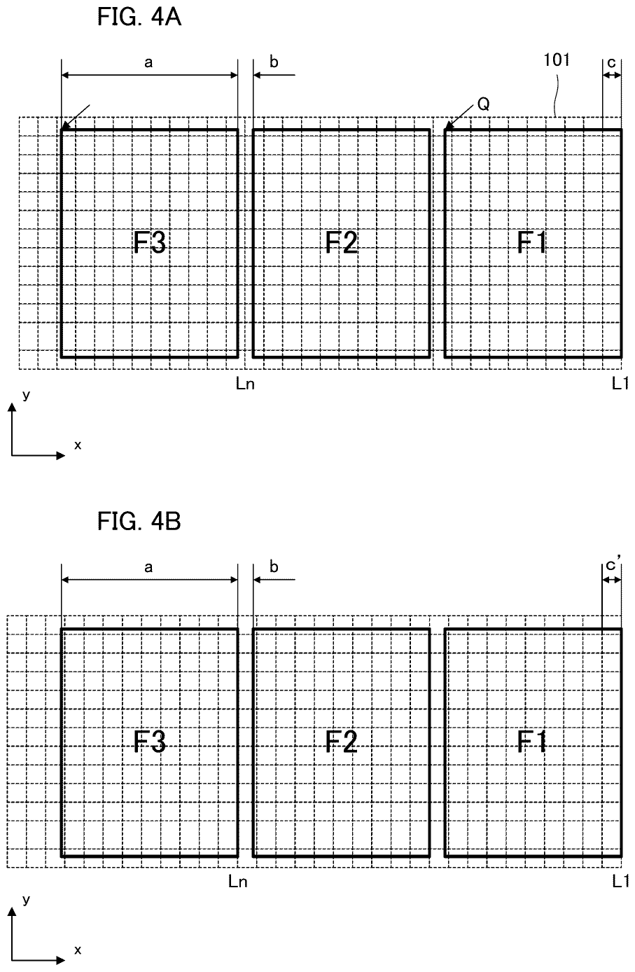

An enlarged view in which fields F1 to F3 are extracted is shown in FIGS. 4A and 4B. The lattice shown in FIGS. 4A and 4B is a grid 101, and discharge material 11 is discharged from the discharge apparatus 10 onto grid points formed by the grid 101. Symbol a represents a length of the field 15 in the x direction (hereinafter, field length), b represents a distance in the x direction between adjacent fields (hereinafter, field interval), and c represents a grid size in the x direction (hereinafter, grid size). In a case in which the dpi value is 1200 dpi, the grid size c is 21.167 μm. That is, the grid size c is a pitch (interval) at which the discharge material 11 is discharged.

In this context, a positional relationship between the grid 101 and the field 15 in FIG. 4A is examined. The right-side edge of the field F1 coincides with the nearest column L1 of the grid 101. However, the right-side edge of the field F3 does not coincide with the nearest column Ln of the grid 101. In this case, because a positional relationship between the field F1 and the grid 101 differs from a positional relationship between the field F3 and the grid 101, the discharge material 11 cannot be discharged in a similar positional relationship with respect to the fields F1 to F3. That is, the discharge material 11 cannot be arranged in the same positional relationship with respect to the fields F1 to F3.

As described above, conventionally, the grid size c is determined by a dpi value and has no relation to the field length a. For this reason, if a discharge position of the discharge material 11 was adjusted in the field F1, there were cases in which a position of the discharge material 11 in the field F3 shifted (deviated).

If the position of the discharge material 11 in the vicinity of an edge of the field 15 shifts and approaches the edge of the field 15, the discharge material 11 protrudes from the field 15 when the mold 3 is imprinted, and the discharge material 11 adheres to a side surface of the mold 3. The discharge material 11 adhered to the side surface of the mold 3 cures during subsequent imprinting, falls from the mold 3 onto the substrate 6 when imprinting is repeated, and is sandwiched between the mold 3 and the substrate 6 during subsequent imprinting, and an imprinting defect may occur.

In addition, if the position of the discharge material 11 in the vicinity of an edge of the field 15 shifts and separates from the edge of the field 15, the discharge material 11 is not filled to the edge of the field 15, and an imprinting defect may occur. For this reason, it is necessary to make a positional relationship between the field 15 and the grid 101 the same in all fields 15.

Thus, a method for making a positional relationship between the field 15 and the grid 101 the same in all fields 15 will be explained, referring to FIG. 4B. In FIG. 4B, a grid size in a movement direction (x direction) of the substrate stage 8 is denoted as c′. In addition, as in FIG. 4A, the field length is denoted as a, the field interval is denoted as b, and, assuming that n is an integer, the grid size c′ is set so as to satisfy the following equation (1).

(a+b)/c′=n (1)

That is, the control unit 12 adjusts the pitch (c′) so that the sum of a width (a) of a shot region in a direction in which the shot region is driven by a drive mechanism and an interval (b) between the shot region and a shot region adjacent in the direction in which the shot region is driven becomes an integer multiple of the pitch (c′) at which discharge is performed.

In a case in which equation (1) is satisfied, the period of the grid size c′ and the period of the total of the field length a and the field interval b match, and therefore the positional relationship between the field 15 and the grid 101 is the same in all fields 15. Accordingly, if a discharge position of the discharge material 11 is adjusted in a certain field 15, the same discharge position performance is obtained in other fields 15.

However, even if a distance of the discharge material 11 from an edge of the field 15 deviates from a desired value to a certain extent, an imprinting defect does not occur if a deviation amount is small. The allowable deviation amount includes, for example, a value equal to or less than 5 μm, and the like. Thus, assuming that n is an integer obtained by rounding off at the first decimal place, equation (1) can be expressed by the following equation (2).

n=int((a+b)/c′) (2)

In addition, the number of fields to be discharged simultaneously is denoted as d. In FIGS. 4A and 4B (FIGS. 3A to 3C), d=12. At this time, if the following equation (3) is satisfied, even when discharge is performed onto 12 fields continuously, a deviation amount of the discharge material 11 in the x direction between the leftmost field F12 and the rightmost field F1 is suppressed to be equal to or less than 5 μm. For example, in a case in which equation (3) is satisfied when the above-described c=21.167 μm is substituted for c′, there is no need to adjust the grid size c.

|(a+b)−nc′|×d≤5 [μm] (3)

That is, the grid size c′ is adjusted so that a difference between a sum of a width a of the field 15 (shot region) in the x direction and a distance b between fields 15 in the x direction, and a value that is an integer multiple of the grid size c′, falls within a predetermined error range.

In addition, in a case in which the grid size in the movement direction (x direction) of the substrate stage 8 is changed from c to c′, the arrangement density of the discharge material 11 becomes c/c′ times the original. For this reason, an amount of the discharge material 11 per unit area also becomes c/c′ times. In order not to change the amount of the discharge material 11 per unit area, it is necessary to multiply the amount per drop of the discharge material 11 discharged from the discharge apparatus 10 by c′/c. That is, the control unit 12 adjusts the amount of the composition discharged from the discharge unit in accordance with the adjusted pitch.

As described above, in order to adjust the size of the grid 101, adjustment of a frequency at which the discharge material 11 is discharged from the discharge apparatus 10 need only be performed. That is, the control unit 12 adjusts the pitch by adjusting a frequency that is a basis of timing at which the discharge unit discharges the composition. For example, in a case in which discharge and imprinting are performed field by field, the grid size c is set to 1200 dpi (=25.4/1200 mm). In a case in which the movement speed of the substrate stage 8 is 1 m/s, the discharge frequency of the discharge material 11 becomes (1 [m/s])/(25.4/1200 [mm])=47.2441 [kHz].

Assuming that the field length a is 26 [mm] and the field interval b is 4 [μm], a+b=26004 [μm]. When (a+b) is divided by the standard grid size c, (a+b)/c=1228.54, and, using n=1229 obtained by rounding off 1228.54 to the nearest integer, the adjusted grid size becomes c′=(26000+4)/1229=21.15867 [μm]. This c′=21.15867 [μm] satisfies the above-described equation (3). At this time, the discharge frequency becomes (1 [m/s])/(0.02115867 [mm])=47.2620 [kHz].

In this manner, by adjusting the frequency at which the discharge material 11 is discharged from the discharge apparatus 10, the period of the field 15 and the period of the grid 101 can be matched, and the position of the discharge material 11 between fields can be aligned. In addition, it is ideal and desirable that a sum of the field length a and the field interval b be an integer multiple of the grid size c′. However, even if there is a certain degree of error, an imprinting defect can be prevented from occurring as long as the above-described equation (3) is satisfied. Furthermore, adjustment of the grid size c′ also does not need to be performed strictly and becomes easy. That is, such an error range is also included in the above-described integer multiple range.

In addition, in order to adjust the size of the grid 101, the movement speed of the substrate stage 8 may be adjusted. That is, the control unit 12 adjusts the pitch by adjusting the movement speed of the substrate driven by the drive mechanism. For example, in a case in which discharge and imprinting are performed field by field, the grid size c is set to 1200 dpi (=25.4/1200 mm). In a case in which the movement speed of the substrate stage 8 is 1 m/s, the discharge frequency of the discharge material 11 becomes 47.2441 [kHz] as described above.

Assuming that the field length a is 26 [mm] and the field interval b is 4 [μm], a+b=26004 [μm]. When (a+b) is divided by the standard grid size c, (a+b)/c=1228.54, and, using n=1229 obtained by rounding off 1228.54 to the nearest integer, the grid size becomes c′=(26000+4)/1229=21.15867 [μm].

Assuming that the movement speed of the substrate stage 8 after adjustment is v′ [m/s], v′=47.2441 [kHz]×0.02115867 [mm]=0.999622 [m/s].

In this manner, by adjusting the movement speed of the substrate stage 8, the period of the field 15 and the period of the grid 101 can be matched, and the position of the discharge material 11 between fields can be aligned.

In addition, another method for making the period of the field 15 and the period of the grid 101 match is to adjust the field interval b. That is, the control unit 12 adjusts an interval between the shot region and a shot region adjacent in the direction in which the shot region is driven. The field interval after adjustment is denoted as b′, and assuming that n is an integer, b′ need only be adjusted so as to satisfy the following equation (4).

(a+b′)/c=n (4)

As described above, even if a distance of the discharge material 11 from an edge of the field 15 deviates from a desired position to a certain extent, an imprinting defect does not occur if the deviation amount is small. Accordingly, similarly to equation (1), assuming that n is an integer obtained by rounding off at the first decimal place, equation (4) can be expressed by the following equation (5).

n=int((a+b′)/c) (5)

In addition, the number of fields to be discharged at one time is set to d=12, and the allowable deviation amount is set to be equal to or less than 5 μm. At this time, if the following equation (6) is satisfied, even when discharge is performed onto 12 fields continuously, a deviation amount of the discharge material 11 in the x direction between the leftmost field F12 and the rightmost field F1 is suppressed to be equal to or less than 5 μm.

|(a+b′)−nc|×d≤5 [μm] (6)

According to the present embodiment, the grid size (pitch) of the discharge material 11 is adjusted so that the sum of the length of the field 15 (shot region) and the distance between the fields 15 (interval between shot regions) becomes an integer multiple of the grid size (pitch). For this reason, occurrence of imprinting defects can be suppressed even when discharge is performed continuously onto a plurality of fields 15. Accordingly, discharge can be performed continuously onto a plurality of fields 15, and throughput of the discharge operation can be improved.

### <Embodiment of Article Manufacturing Method>

A pattern of a cured product formed by using an imprint apparatus is used permanently for at least a part of various articles, or temporarily when manufacturing various articles. The articles include an electric circuit element, an optical element, a MEMS, a recording element, a sensor, a mold, and the like. Examples of the electric circuit element include volatile or non-volatile semiconductor memories such as a DRAM, an SRAM, a flash memory, and an MRAM, and semiconductor elements such as an LSI, a CCD, an image sensor, and an FPGA, and the like. Examples of the mold include a mold for imprinting, and the like.

The pattern of the cured product is used directly as a constituent member of at least a part of the above-described articles, or is temporarily used as a resist mask. After etching or ion implantation and the like is performed in a processing step of the substrate, the resist mask is removed.

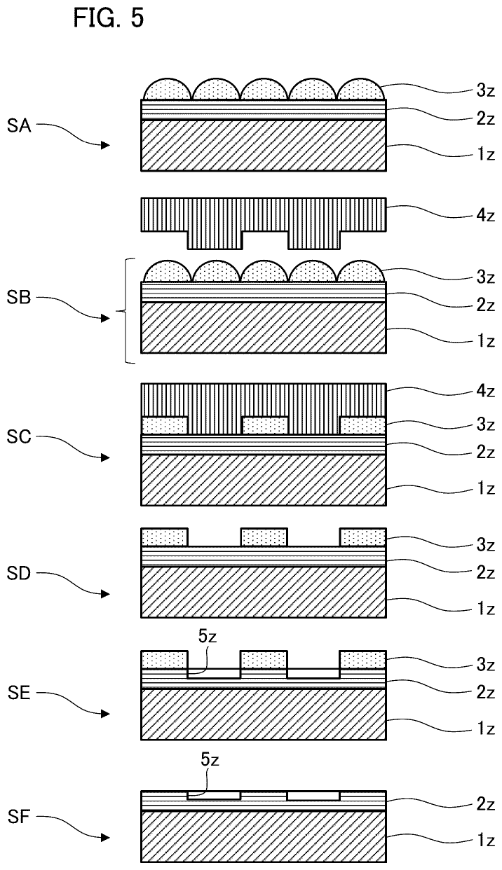

Next, a specific manufacturing method of the article will be explained with reference to FIG. 5. First, as shown in step SA, a substrate 1z such as a silicon wafer having a workpiece 2z such as an insulator formed on a surface thereof is prepared, and subsequently, a composition 3z is applied to the surface of the workpiece 2z by an inkjet method and the like. A state in which the composition 3z in the form of a plurality of droplets is applied onto the substrate is shown here.

Next, as shown in step SB, a mold 4z for imprinting is arranged such that the side on which the uneven pattern is formed faces the composition 3z on the substrate. Then, as shown in step SC, the substrate 1z to which the composition 3z is applied and the mold 4z are brought into contact, and pressure is applied. The composition 3z is filled into a gap between the mold 4z and the workpiece 2z. When light is irradiated through the mold 4z as energy for curing in this state, the composition 3z is cured.

Next, as shown in step SD, after the composition 3z is cured, when the mold 4z and the substrate 1z are separated, a pattern of a cured product of the composition 3z is formed on the substrate 1z. The pattern of the cured product has a shape in which a concave portion of the mold corresponds to a convex portion of the cured product, and a convex portion of the mold corresponds to a concave portion of the cured product. That is, the uneven pattern of the mold 4z is transferred to the composition 3z.

Next, as shown in step SE, when etching is performed using the pattern of the cured product as an etching-resistant mask, a portion of the surface of the workpiece 2z in which the cured product is absent or remains thin is removed, and groove 5z is thereby formed. Then, as shown in step SF, when the pattern of the cured product is removed, an article having the groove 5z formed on a surface of the workpiece 2z can be obtained. Although the pattern of the cured product is removed in step SF, the pattern of the cured product may be used without being removed even after processing, for example, as a film for interlayer insulation included in a semiconductor element and the like, that is, as a constituent member of the article.

### Other Embodiments

The preferred embodiments of the present disclosure have been explained above, although the present disclosure is not limited to these embodiments, and various modifications and changes are possible within the scope of the gist thereof. The present disclosure can also be realized by processing in which a program realizing one or more functions of the above-described embodiments is supplied to a system or an apparatus via a network or a storage medium, and one or more processors of a computer of the system or the apparatus read out and execute the program. The present disclosure can also be realized by a circuit (for example, an ASIC) realizing one or more functions.

According to the present disclosure, occurrence of imprinting defects can be suppressed even when discharge is performed continuously onto a plurality of shot regions.

Embodiment(s) of the present disclosure can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2025-072882, filed Apr. 25, 2025, which is hereby incorporated by reference herein in its entirety.

What is claimed is:

1. A molding apparatus configured to mold a composition disposed in a plurality of shot regions on a substrate by using a mold, the molding apparatus comprising:
a discharge unit configured to discharge the composition onto the substrate;
a drive mechanism configured to drive the substrate relative to the discharge unit;
at least one memory storing instructions; and
at least one processor executing the stored instructions causing the molding apparatus to:
discharge the composition from the discharge unit at a predetermined pitch onto the substrate driven by the drive mechanism, and
adjust so that a sum of a width of the shot region in a driven direction in which the shot region is driven by the drive mechanism and an interval between the shot region and a shot region adjacent in the driven direction becomes an integer multiple of the pitch.

2. The molding apparatus according to claim 1, wherein executing the stored instructions by the processor further causes the molding apparatus to adjust the pitch.

3. The molding apparatus according to claim 2, wherein executing the stored instructions by the processor further causes the molding apparatus to adjust the pitch by adjusting a frequency that is a basis for timing at which the discharge unit discharges the composition.

4. The molding apparatus according to claim 2, wherein executing the stored instructions by the processor further causes the molding apparatus to adjust the pitch by adjusting a movement speed of the substrate driven by the drive mechanism.

5. The molding apparatus according to claim 2, wherein executing the stored instructions by the processor further causes the molding apparatus to adjust an amount of the composition discharged from the discharge unit in accordance with the adjusted pitch.

6. The molding apparatus according to claim 1, wherein executing the stored instructions by the processor further causes the molding apparatus to adjust the interval.

7. An imprint method for molding a composition disposed in a plurality of shot regions on a substrate by using a mold, the imprint method comprising:
driving the substrate relative to a discharge unit;
discharging the composition from the discharge unit at a predetermined pitch onto the substrate being driven in the driving; and
adjusting the pitch so that a sum of a width of the shot region in a driven direction in which the shot region is driven in the driving and an interval between the shot region and a shot region adjacent in the driven direction becomes an integer multiple of the pitch.

8. An imprint method for molding a composition disposed in a plurality of shot regions on a substrate by using a mold, the imprint method comprising:
driving the substrate relative to a discharge unit;
discharging the composition from the discharge unit at a predetermined pitch onto the substrate being driven in the driving; and
adjusting the interval so that a sum of a width of the shot region in a driven direction in which the shot region is driven in the driving and an interval between the shot region and a shot region adjacent in the driven direction becomes an integer multiple of the pitch.

9. An article manufacturing method comprising:
forming a pattern on a substrate in accordance with the imprint method according to claim 7;
processing the substrate on which the pattern is formed; and
manufacturing an article from the processed substrate.
